(19) United States
(12) Patent Application Publication
(10) Pub. No.: US 2023/0335476 A1
(43) Pub. Date: Oct. 19, 2023

(54) SEMICONDUCTOR PACKAGE AND METHOD OF FABRICATING THE SAME

(71) Applicant: Samsung Electronics Co., Ltd., Suwon-si (KR)

(72) Inventors: Dae Hun Lee, Suwon-si (KR); Sung Bum Kim, Suwon-si (KR); Yun Seok Choi, Suwon-si (KR)

(73) Assignee: Samsung Electronics Co., Ltd., Suwon-si (KR)

(21) Appl. No.: 18/164,851

(22) Filed: Feb. 6, 2023

(30) Foreign Application Priority Data
Apr. 18, 2022 (KR) 10-2022-0047370

(51) Int. Cl. H01L 23/498; H01L 21/48; H01L 21/56; H01L 23/00; H01L 23/31; H01L 25/10

(52) U.S. Cl. CPC H01L 23/49816; H01L 21/4853; H01L 21/565; H01L 24/16; H01L 24/32; H01L 24/73; H01L 23/49833; H01L 23/49838; H01L 23/49866; H01L 23/3128; H01L 23/3135; H01L 25/105; H01L 2924/1438; H01L 2924/1436; H01L 2924/1431; H01L 2924/3512; H01L 21/563; H01L 2224/73204; H01L 2224/32225; H01L 2224/16227; H01L 2225/1023; H01L 2225/1041; H01L 2225/1058

(57) ABSTRACT

A semiconductor package includes a wiring structure including a first insulating layer and a first wiring pad. The first wiring pad is in the first insulating layer. The package includes a semiconductor chip on the wiring structure, and an interposer on the semiconductor chip. The interposer includes a second insulating layer and a second wiring pad, and the second wiring pad is in the second insulating layer. The package includes a first connecting structure including a first metal layer and a second metal layer surrounding the first metal layer. The first metal layer includes a lower metal layer adjacent to the wiring structure and an upper metal layer adjacent to the interposer, and the first connecting structure connects the first wiring pad and the second wiring pad. The package includes a mold layer between the wiring structure and the interposer.

### CROSS-REFERENCE TO RELATED APPLICATION

This application claims priority from Korean Patent Application No. 10-2022-0047370 filed on Apr. 18, 2022 in the Korean Intellectual Property Office, and all the benefits accruing therefrom under 35 U.S.C. 119, the contents of which in its entirety are herein incorporated by reference.

### FIELD

Some of the example embodiments relate to a semiconductor package and/or a method of fabricating the same, including a semiconductor package including an interposer and/or a method of fabricating the same.

### BACKGROUND

Due to development of an electronic industry, there are increasing demands for higher functionality, higher speed and miniaturization of electronic components. In response to such a tendency, a method of stacking and mounting a plurality of semiconductor chips on a single package wiring structure or a method of stacking a package on the package may be used. For example, a package-in-package (PIP) type semiconductor package or a package-on-package (POP) type semiconductor package may be used.

The POP type semiconductor package may include an interposer for electrically connecting the packages between an upper package and a lower package. The interposer may facilitate the connection between the upper package and the lower package and inhibit or prevent warpage of the upper package and the lower package.

### SUMMARY

Some aspects of the inventive concepts provide a semiconductor package in which a connecting structure in which a plurality of core layers are stacked is formed between an interposer and a semiconductor chip, and a pitch between the connecting structures is reduced.

Some aspects of the inventive concepts provide a method of fabricating a semiconductor package in which a connecting structure in which a plurality of core layers are stacked is formed between an interposer and a semiconductor chip, and the pitch between the connecting structures is reduced.

According to an example embodiment of the inventive concepts, a semiconductor package includes a wiring structure including a first insulating layer and a first wiring pad, wherein the first wiring pad is in the first insulating layer, a semiconductor chip on the wiring structure, an interposer on the semiconductor chip, wherein the interposer includes a second insulating layer and a second wiring pad, and the second wiring pad is in the second insulating layer. The package includes a first connecting structure including a first metal layer and a second metal layer surrounding the first metal layer, wherein the first metal layer includes a lower metal layer adjacent to the wiring structure and an upper metal layer adjacent to the interposer, and the first connecting structure connects the first wiring pad and the second wiring pad, and a mold layer between the wiring structure and the interposer.

According to some example embodiments of the inventive concepts, a semiconductor package includes a first semiconductor package, and a second semiconductor package placed on the first semiconductor package. The first semiconductor package includes a wiring structure including a first insulating layer and a first wiring pad, the first wiring pad in the first insulating layer, a semiconductor chip on a first surface of the wiring structure, an interposer having a first surface facing the semiconductor chip, the interposer including a second insulating layer and a second wiring pad in the second insulating layer, a connecting structure between the wiring structure and the interposer, and a mold layer integrally covering the connecting structure and an upper surface of the semiconductor chip. The connecting structure includes a plurality of core layers and a metal layer surrounding the plurality of core layers.

According to some example embodiments of the inventive concepts, a method of fabricating a semiconductor package includes forming a first wiring structure including a first insulating layer and a first wiring pad, wherein a semiconductor chip and a first pre-connecting structure are on a first surface of the first wiring structure, forming a second wiring structure including a second insulating layer and a second wiring pad, wherein a second pre-connecting structure is on a first surface of the second wiring structure, and joining the first and second pre-connecting structures with the first surface of the first wiring structure and the first surface of the second wiring structure facing each other to form a connecting structure. The method includes forming a mold layer covering an upper surface of the semiconductor chip, wherein the first pre-connecting structure includes a first pre-lower metal layer and a second pre-lower metal layer surrounding the first pre-lower metal layer, the second pre-connecting structure includes a first pre-upper metal layer and a second pre-upper metal layer surrounding the first pre-upper metal layer, and joining the second pre-lower metal layer and the second pre-upper metal layer to join the first and second pre-connecting structures. However, aspects of the inventive concepts are not restricted to the ones set forth herein. The above and other aspects of the inventive concepts will become more apparent by referencing the detailed description of the inventive concepts given below.

### BRIEF DESCRIPTION OF THE DRAWINGS

The above and other aspects and features of the inventive concepts will become more apparent by describing in detail example embodiments thereof with reference to the attached drawings, in which:

FIGS. 1 and 2 are diagrams for explaining an electronic device according to some example embodiments;

FIG. 3 is a diagram for explaining a semiconductor package and a main board of FIG. 2;

FIG. 4 is an example layout diagram of a semiconductor package according to some example embodiments of FIG. 3;

FIG. 5 is a diagram showing a semiconductor package according to some example embodiments taken along I-I′ of FIG. 4;

FIG. 6 is an enlarged view for explaining a region 51 of FIG. 5;

FIG. 7 is a diagram which shows the semiconductor package according to some example embodiment, and corresponds to FIG. 5;

FIG. 8 is an example layout diagram of a semiconductor package according to some example embodiments of FIG. 3;

FIG. 9 is a diagram showing a semiconductor package according to some example embodiments taken along II-IF of FIG. 8;

FIG. 10 is an enlarged view for explaining a region S2 of FIG. 9;

FIG. 11 is a diagram which shows the semiconductor package according to some example embodiments, and corresponds to FIG. 10;

FIG. 12 is a diagram which shows a semiconductor package according to some example embodiments taken along I-I′ of FIG. 4;

FIG. 13 is a diagram showing a semiconductor package according to some example embodiments taken along I-I′ of FIG. 4;

FIGS. 14, 15, 16, 17 and 18 are intermediate stage diagrams for explaining a method of fabricating a semiconductor package according to some example embodiments.

### DETAILED DESCRIPTION

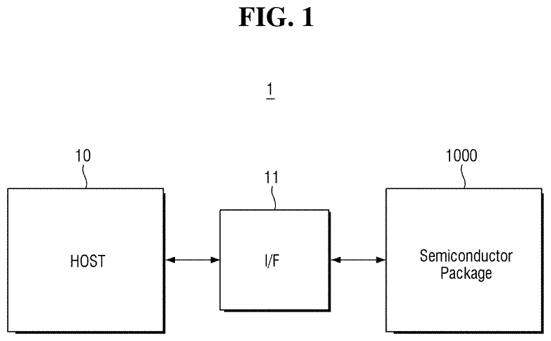

Hereinafter, a semiconductor package according to some example embodiments will be described with reference to FIGS. 1 to 6.

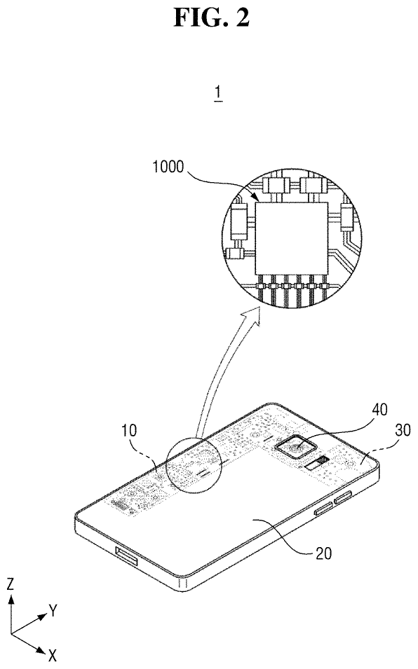

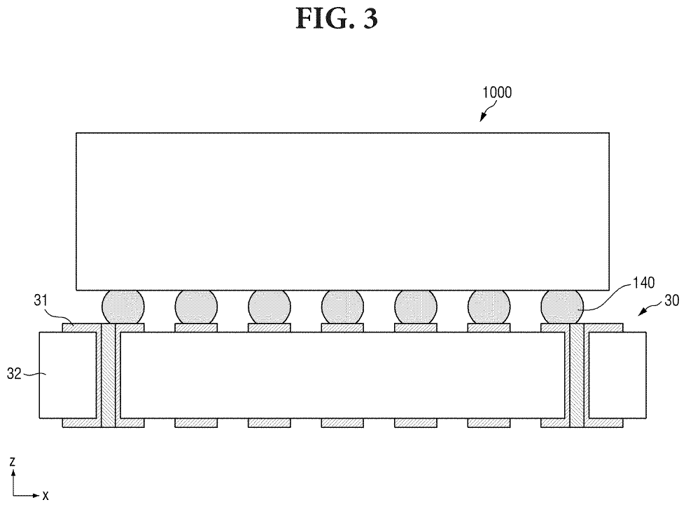

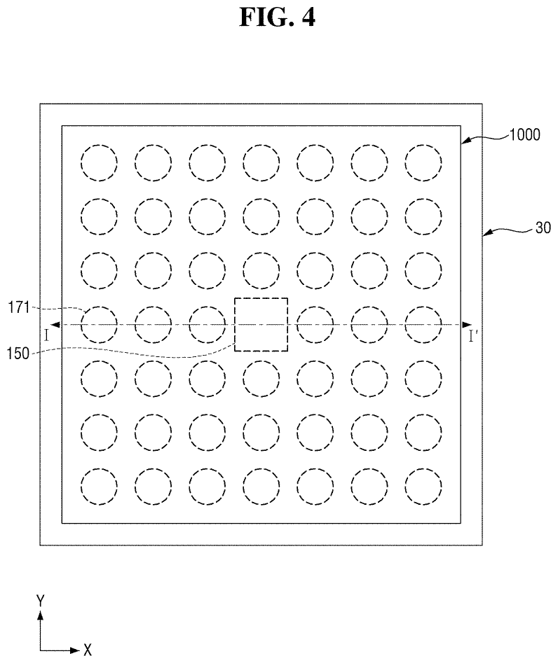

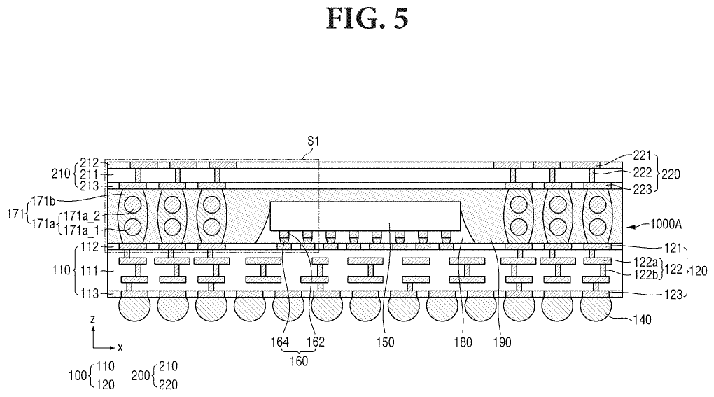

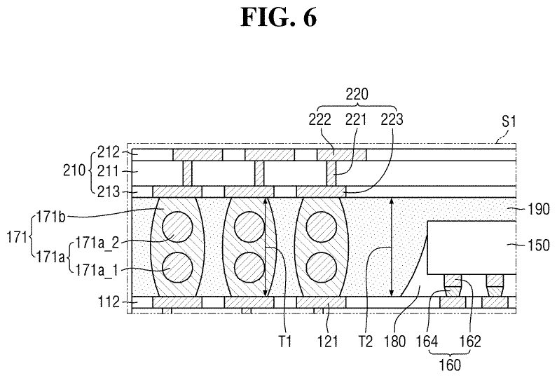

FIGS. 1 and 2 are diagrams for explaining an electronic device according to some example embodiments. FIG. 3 is a diagram for explaining a semiconductor package and a main board of FIG. 2. FIG. 4 is an example layout diagram of a semiconductor package according to some example embodiments of FIG. 3. FIG. 5 is a diagram showing a semiconductor package according to some example embodiments taken along I-I′ of FIG. 4. FIG. 6 is an enlarged view for explaining a region 51 of FIG. 5.

Referring to FIG. 1, the electronic device 1 may include a host 10, an interface 11, and a semiconductor package 1000.

In some example embodiments, the host 10 may be connected to the semiconductor package 1000 through the interface 11. For example, the host 10 may transmit a signal to the semiconductor package 1000 to control the semiconductor package 1000. Further, for example, the host 10 may receive the signal from the semiconductor package 1000 and process the data included in the signal.

For example, the host 10 may include a central processing unit (CPU), a controller, an application specific integrated circuit (ASIC), and the like. Further, for example, the host 10 may include a memory chip, such as a DRAM (Dynamic Random Access Memory), a SRAM (Static RAM), a PRAM (Phase-change RAM), a MRAM (Magneto resistive RAM), a FeRAM (Ferroelectric RAM) and a RRAM (Resistive RAM), but example embodiments are not limited thereto.

Referring to FIGS. 1 and 2, the electronic device 1 may include a host 10, a body 20, a main board 30, a camera module 40, and a semiconductor package 1000.

The main board 30 may be mounted inside the body 20 of the electronic device 1. The host 10, the camera module 40, and the semiconductor package 1000 may be mounted on the main board 30. The host 10, the camera module 40, and the semiconductor package 1000 may be electrically connected by the main board 30. For example, the interface 11 may be implemented by the main board 30.

The host 10 and the semiconductor package 1000 may be electrically connected by the main board 30 to transmit and receive signals.

Referring to FIG. 3, the semiconductor package 1000 may be placed on the main board 30. For example, a first connecting terminal 140 may be placed on the main board 30. The main board 30 may be connected to the semiconductor package 1000 by the first connecting terminal 140.

The main board 30 may be a printed circuit wiring structure (e.g., a printed circuit board: PCB), a ceramic wiring structure, a glass wiring structure, an interposer wiring structure, or the like. However, the example embodiments according to technical ideas of the inventive concepts are not limited thereto. For convenience of explanation, the description will be provided on the assumption that the main board 30 is a printed circuit wiring structure.

The main board 30 may include a connecting structure 31 and a core 32. The core 32 may include a CCL (Copper Clad Laminate), a PPG, an ABF (Ajinomoto Build-up Film), epoxy, polyimide, and the like. The connecting structure 31 may include, but not limited to, at least one of copper (Cu), aluminum (Al), silver (Ag), tin (Sn), gold (Au), nickel (Ni), lead (Pb), titanium (Ti), and alloys thereof.

The core 32 is placed at a central part of the main board 30, and the connecting structure 31 may be placed above and below the core 32. The connecting structure 31 may be placed to be exposed above and below the main board 30.

Further, the connecting structure 31 may be placed to penetrate the core 32. The connecting structure 31 may electrically connect elements that come into contact with the main board 30. For example, the connecting structure 31 may electrically connect the semiconductor package 1000 and the host 10. That is, the connecting structure 31 may electrically connect the semiconductor package 1000 and the host 10 through the first connecting terminal 140.

Referring to FIGS. 4 and 5, the semiconductor package 1000 according to some example embodiments includes a first semiconductor package 1000A that includes a first wiring structure 100, a first semiconductor chip 150, an interposer 200, a first connecting structure 171, and a first mold layer 190.

The first wiring structure 100 may be a wiring structure for packaging. For example, the first wiring structure 100 may be a printed circuit wiring structure (e.g., a PCB; printed circuit board), a ceramic wiring structure, or the like. The first wiring structure 100 may be a wiring structure for a wafer level package (WLP) fabricated at a wafer level. The first wiring structure 100 may include a lower surface and an upper surface that are opposite to each other.

The first wiring structure 100 includes a first insulating layer 110 and a first wiring layer 120. The first insulating layer 110 may include a first substrate 111, a first lower passivation film 113, and a first upper passivation film 112. The first wiring layer 120 may include a first lower pad 123, a first wiring pad 122, and a first upper pad 121.

The first substrate 111 may be, for example, a printed circuit board (PCB) or a ceramic substrate. However, the example embodiments of the inventive concepts are not limited thereto.

When the first substrate 111 is a printed circuit board, the first insulating layer 110 may be made up of at least one material selected from phenol resin, epoxy resin, and polyimide. The first insulating layer 110 may include, for example, at least one material selected from FR-4, tetrafunctional epoxy, polyphenylene ether, epoxy/polyphenylene oxide, BT (bismaleimide triazine), THERMOUNT® laminate and prepreg for printed circuit boards (e.g., nonwoven aramid fiber reinforced substrate for printed wiring boards), cyanate ester, polyimide, and liquid crystal polymer, but example embodiments are not limited thereto. The surface of the first substrate 111 may be covered with a solder resist. That is, the first lower passivation film 113 and the first upper passivation film 112 formed on the surface of the first substrate 111 may be solder resists. However, the example embodiments of the inventive concepts are not limited thereto.

The first wiring pad 122 may be placed inside the first insulating layer 110. The first wiring layer 120 may be made up of a first wiring pad 122 for electrically connecting the first lower pad 123 and the first upper pad 121. The first wiring pad 122 may include a plurality of wiring vias 122b that connect the plurality of wiring patterns 122a and each wiring.

Although the first substrate 111 is shown as a single layer, this is only for convenience of explanation. For example, the first substrate 111 may be made up of multiple layers to form the first wiring pad 122 of multiple layers.

In some example embodiments, the first connecting terminal 140 may be formed on the lower surface of the first wiring structure 100. The first connecting terminal 140 may be attached to the first lower pad 123. The first connecting terminal 140 may have, for example, but is not limited to, a spherical shape or elliptical spherical shape.

Although the first connecting terminal 140 may include, for example, at least one of tin (Sn), indium (In), lead (Pb), zinc (Zn), nickel (Ni), gold (Au), silver (Ag), copper (Cu), antimony (Sb), bismuth (Bi), and combinations thereof, the example embodiments of the inventive concepts are not limited thereto.

The first connecting terminal 140 may electrically connect the first wiring structure 100 to an external device. Accordingly, the first connecting terminal 140 may provide an electric signal to the first wiring structure 100, or may provide an electric signal, which is provided from the first wiring structure 100, to an external device.

The first upper passivation film 112 and the first upper pad 121 may be formed on the upper surface of the first substrate 111. The first upper passivation film 112 may cover the upper surface of the first substrate 111 and expose the first upper pad 121.

The first lower passivation film 113 and the first lower pad 123 may be formed on the lower surface of the first substrate 111. The first lower passivation film 113 may cover the lower surface of the first substrate 111 and expose the first lower pad 123.

In some example embodiments, the first upper pad 121 may be electrically connected to the first lower pad 123. For example, the first upper pad 121 may be electrically connected to the first lower pad 123 by coming into contact with the first wiring pad 122.

The first upper passivation film 112 and the first lower passivation film 113 may include, for example, but is not limited to, photoimageable dielectric (PID).

The first semiconductor chip 150 may be placed on the first wiring structure 100. For example, the first semiconductor chip 150 may be mounted on the upper surface of the first wiring structure 100. The first semiconductor chip 150 may include an integrated circuit (IC) in which hundreds to millions or more semiconductor elements are integrated in a single chip. For example, the first semiconductor chip 150 may be, but not limited to, an application processor (AP), such as a CPU (Central Processing Unit), a GPU (Graphic Processing Unit), an FPGA (Field-Programmable Gate Array), a digital signal processor, an encryption processor, a micro processor, and a micro controller. For example, the first semiconductor chip 150 may be a logic chip such as an ADC (Analog-Digital Converter) or an ASIC (Application-Specific IC), and may be a memory chip such as a volatile memory (e.g., a DRAM) or a non-volatile memory (e.g., a ROM or a flash memory), but example embodiments are not limited thereto. The first semiconductor chip 150 may be formed by combining these elements with each other.

Although only one first semiconductor chip 150 is shown as being formed on the first wiring structure 100, this is merely for convenience of explanation. For example, a plurality of first semiconductor chips 150 may be formed side by side on the first wiring structure 100, or a plurality of first semiconductor chips 150 may be sequentially stacked on the first wiring structure 100.

In some example embodiments, the first semiconductor chip 150 may be mounted on the first wiring structure 100 by a flip chip bonding method. For example, the first bump 160 may be formed between the upper surface of the first wiring structure 100 and the lower surface of the first semiconductor chip 150. The first bump 160 may electrically connect the first wiring structure 100 and the first semiconductor chip 150.

The first bump 160 may include, for example, a first pillar layer 162 and a first solder layer 164.

The first pillar layer 162 may protrude from the lower surface of the first semiconductor chip 150. The first pillar layer 162 may include, for example, but is not limited to, copper (Cu), copper alloy, nickel (Ni), palladium (Pd), platinum (Pt), gold (Au), cobalt (Co), and combinations thereof.

The first solder layer 164 may connect the first pillar layer 162 and the first wiring structure 100. For example, the first solder layer 164 may be electrically connected to a part of the first upper pads 121. The first solder layer 164 may have, for example, but is not limited to, a spherical shape or elliptical spherical shape. The first solder layer 164 may include, for example, but is not limited to, tin (Sn), indium (In), bismuth (Bi), antimony (Sb), copper (Cu), silver (Ag), zinc (Zn), lead (Pb), and combinations thereof.

An underfill material 180 may be formed on the first wiring structure 100. The underfill material 180 may fill up a region between the first wiring structure 100 and the first semiconductor chip 150. The underfill material 180 may inhibit or prevent the first semiconductor chip 150 from cracking or the like by fixing the first semiconductor chip 150 on the first wiring structure 100. The underfill material 180 may cover the first bump 160. The first bump 160 may penetrate the underfill material 180 to electrically connect the first wiring structure 100 and the first semiconductor chip 150.

The underfill material 180 may include, but is not limited to, an insulating polymer material such as, for example, EMC (epoxy molding compound). In some example embodiments, the underfill material 180 may include a material different from that of the first mold layer 190 to be described below. For example, the underfill material 180 may include an insulating material having fluidity that is superior to that of the first mold layer 190. Therefore, the underfill material 180 may efficiently fill up the narrow space between the first wiring structure 100 and the first semiconductor chip 150.

The interposer 200 may be interposed between the first wiring structure 100 and a third wiring structure 300 to be described later. For example, the interposer 200 may be placed on the first wiring structure 100 and upper surface of the first semiconductor chip 150. In some example embodiments, the interposer 200 may mean a second wiring structure 200. The interposer 200 may facilitate the connection between the first wiring structure 100 and the third wiring structure 300. Further, the interposer 200 may inhibit or prevent a warpage phenomenon between the first wiring structure 100 and the third wiring structure 300.

The interposer 200 may include a lower surface and an upper surface that are opposite to each other. For example, the lower surface of the interposer 200 may face upper surface of the first wiring structure 100, and the upper surface of the interposer may face the lower surface of the third wiring structure 300 to be described below.

The interposer 200 may be spaced apart from the first wiring structure 100. Further, the interposer 200 may be spaced apart from the first semiconductor chip 150.

The interposer 200 may include a second insulating layer 210 and a second wiring layer 220. The second insulating layer 210 may include a second lower passivation film 213, a second substrate 211 and a second upper passivation film 212. The second wiring layer 220 may include a second lower pad 223, a second wiring pad 222 and a second upper pad 221.

The second substrate 211 may be, for example, a printed circuit board (PCB) or a ceramic substrate. However, the example embodiments of the inventive concepts are not limited thereto. In some example embodiments, the interposer 200 may include silicon (Si).

The second wiring layer 220 may be placed inside the second insulating layer 210. The second wiring layer 220 may be formed of a second wiring pad 222 for electrically connecting the second lower pad 223 and the second upper pad 221.

Although the second substrate 211 is shown as a single layer, this is only for convenience of explanation. For example, the second substrate 211 may be made up of multiple layers and form the second wiring pad 222 of the multiple layers.

The second upper passivation film 212 and the second upper pad 221 may be formed on the upper surface of the second substrate 211. The second upper passivation film 212 may cover the upper surface of the second substrate 211 and expose the second upper pad 221.

The second lower passivation film 213 and the second lower pad 223 may be formed on the lower surface of the second substrate 211. The second lower passivation film 213 may cover the lower surface of the second substrate 211 and expose the second lower pad 223.

In some example embodiments, the second upper pad 221 may be electrically connected to the second lower pad 223. For example, the second upper pad 221 may be electrically connected to the second lower pad 223 by coming into contact with the second wiring pad 222.

The second lower passivation film 213 and the second upper passivation film 212 may include, for example, but is not limited to, a photoimageable dielectric 1 (PID).

The first connecting structure 171 may be interposed between the first wiring structure 100 and the interposer 200. The first connecting structure 171 may come into contact with the upper surface of the first wiring structure 100 and the lower surface of the interposer 200.

The first connecting structure 171 may be placed on the outside of the first semiconductor chip 150 to support the first wiring structure 100 and the interposer 200.

The first connecting structure 171 may electrically connect the first wiring structure 100 and the interposer 200. For example, the first connecting structure 171 may come into contact with the first upper pad 121 of the first wiring structure 100 and the second lower pad 223 of the interposer 200. As a result, the first connecting structure 171 may electrically connect the first wiring layer 120 and the second wiring layer 220.

The first connecting structure 171 may include a plurality of first metal layers 171a and a second metal layer 171b that surrounds the plurality of first metal layers 171a.

The plurality of first metal layers 171a may include a first 1 metal layer 171a_1, and a first 2 metal layer 171a_2 stacked on the first 1 metal layer 171a_1. The first 2 metal layer 171a_2 may be stacked on the first 1 metal layer 171a_1 in a first direction (thickness direction) Z. The first 1 metal layer 171a_1 and the first 2 metal layer 171a_2 may be spaced apart from each other in the first direction Z. The first 1 metal layer 171a_1 is placed adjacent to the upper surface of the first wiring structure 100, and the first 2 metal layer 171a_2 may be placed adjacent to the lower surface of the interposer 200. However, the example embodiments of the inventive concepts are not limited thereto.

The second metal layer 171b may come into connect with each of the first upper pad 112 of the first wiring structure 100 and the second lower pad 223 of the interposer 200 to connect them.

Each of the first 1 metal layer 171a_1 and the first 2 metal layer 171a_2 may have, for example, but is not limited to, a spherical shape or an elliptical spherical shape. For example, the first 1 metal layer 171a_1 may be a core layer including copper (Cu), and the first 2 metal layer 171a_2 may be a solder layer including tin (Sn). In some example embodiments, the first connecting structure 171 may not include the insulating polymer material.

The first mold layer 190 may be formed on the first wiring structure 100. The first mold layer 190 may fill the space between the first wiring structure 100 and the interposer 200. Therefore, the first mold layer 190 may cover and protect the first wiring structure 100, the first semiconductor chip 150, the first bump 160, and the first connecting structure 171.

The first connecting structure 171 may penetrate the first mold layer 190 and electrically connect the first wiring structure 100 and the interposer 200. The first mold layer 190 may integrally cover the upper surface of the first semiconductor chip 150 and the side surface of the first connecting structure 171.

The first mold layer 190 may include an insulating polymer material such as EMC (epoxy molding compound). The first mold layer 190 is a thermosetting resin such as an epoxy resin, a thermoplastic resin such as polyimide, or a resin in which a reinforcing material such as a filler is included in these elements, for example, ABF, FR-4, BT resin and the like.

The filler may utilize at least one or more selected from a group including silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃). However, the material of the filler is not limited thereto, and may include a metal material and/or an organic material.

Referring to FIG. 6, a thickness T1 of the first connecting structure 171 may be the same as a thickness T2 of the first mold layer 190. As will be described later, after the first connecting structure 171 is formed, the first mold layer 190 may be formed to integrally cover the upper surface of the first semiconductor chip 150 and the side surface of the first connecting structure 171. Therefore, the thickness T1 of the first connecting structure 171 may be substantially the same as the thickness T2 of the first mold layer 190.

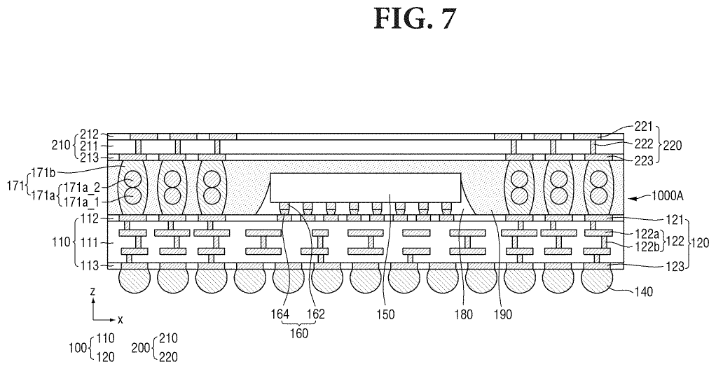

FIG. 7 is a diagram which shows the semiconductor package according to some example embodiments, and corresponds to FIG. 5. For convenience of explanation, points different from those described using FIGS. 1 to 6 will be mainly described.

Referring to FIG. 7, the first 1 metal layer 171a_1 and the first 2 metal layer 171a_2 may be in contact with each other in the first direction Z. In a TC (thermal compression) bonding procedure to be described later, while a part of the solder layer of the first connecting structure 171 is melted by high-temperature compression, a plurality of copper core layers may be pushed in a vertical direction to come into contact with each other.

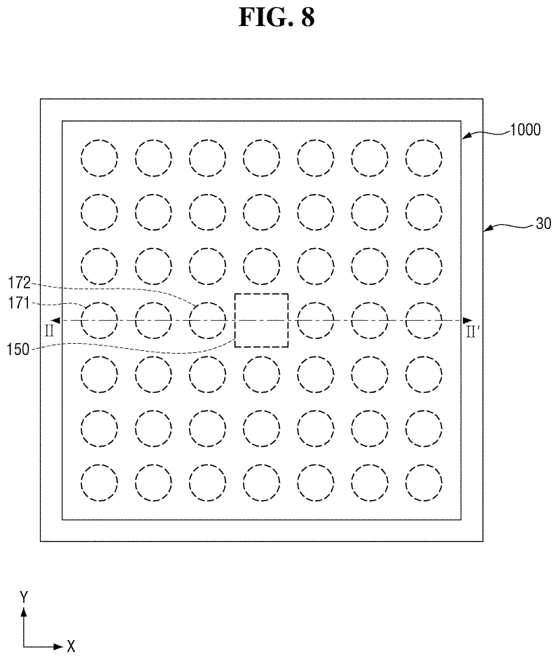

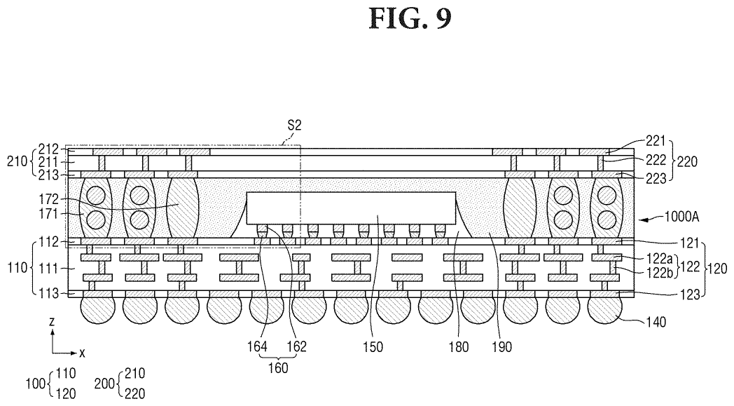

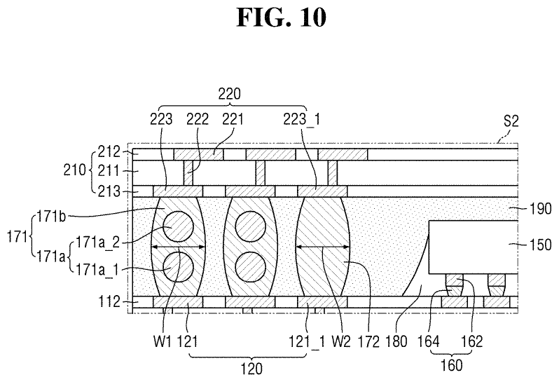

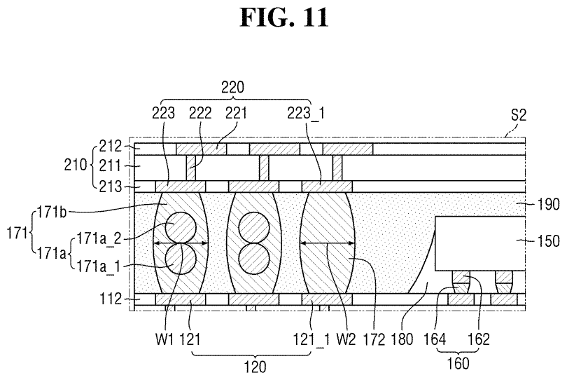

FIG. 8 is an example layout diagram of a semiconductor package according to some example embodiments of FIG. 3. FIG. 9 is a diagram showing a semiconductor package according to some example embodiments taken along II-IF of FIG. 8. FIG. 10 is an enlarged view for explaining a region S2 of FIG. 9. FIG. 11 is a diagram which shows the semiconductor package according to some example embodiments, and corresponds to FIG. 10. For convenience of explanation, points different from those described using FIGS. 1 to 6 will be mainly described.

With reference to FIGS. 8 and 9, the semiconductor package according to some example embodiments may further include a second connecting structure 172 placed apart from the first connecting structure 171. The first connecting structure 171 and the second connecting structure 172 may each be separately placed in a second direction X and a third direction Y, which intersect the first direction Z. The second connecting structure 172 may be placed to be closer to the first semiconductor chip 150 than the first connecting structure 171. However, the example embodiments of the inventive concepts are not limited thereto.

On the other hand, although the number of the second connecting structure 172 is shown to be two in FIG. 9, the number of the second connecting structure 172 is not limited thereto, and the number may be other than two.

The second connecting structure 172 may be interposed between the first wiring structure 100 and the interposer 200. The second connecting structure 172 may come into contact with the upper surface of the first wiring structure 100 and the lower surface of the interposer 200. The second connecting structure 172 may support the first wiring structure 100 and the interposer 200 together with the first connecting structure 171 placed outside the first semiconductor chip 150.

The second connecting structure 172 may electrically connect the first wiring structure 100 and the interposer 200. For example, referring to FIG. 10, the second connecting structure 172 comes into contact with the first 1 upper pad 121_1 of the first wiring structure 100 and the first 1 lower pad 223_1 of the interposer 200. As a result, the second connecting structure 172 may electrically connect the first wiring layer 120 and the second wiring layer 220.

The second connecting structure 172 may have, for example, but is not limited to, a spherical shape or an elliptical spherical shape. The second connecting structure 172 may include, for example, tin (Sn). However, unlike the first connecting structure 171, the second connecting structure 172 may not include copper (Cu).

Referring to FIG. 10, when the first 1 metal layer 171a_1 and the first 2 metal layer 171a_2 are spaced apart from each other, the width W1 of the first connecting structure 171 and the width W2 of the second connecting structure 172 may be the same or substantially the same as each other. That is, the diameter of the first connecting structure 171 may be substantially the same as the diameter of the second connecting structure 172 on the basis of the second direction X.

Referring to FIG. 11, when the first 1 metal layer 171a_1 and the first 2 metal layer 171a_2 come into contact with each other, the width W1 of the first connecting structure 171 and the width W2 of the second connecting structure 172 may be the same or substantially the same as each other. That is, the diameter of the first connecting structure 171 of the portion in which the first 1 metal layer 171a_1 and the first 2 metal layer 171a_2 are in contact with each other may be substantially the same as the diameter of the second connecting structure 172 on the basis of the second direction X.

According to some example embodiments, by interposing the first connecting structure 171 in which a core layer is formed between the interposer 200 and the semiconductor chip 150, a distance between the lower surface of the interposer 200 and the semiconductor chip 150 may be maintained properly and misalignment between the first wiring structure 100 and the interposer 200 may be reduced or minimized. Further, by interposing the first connecting structure 171 including a plurality of stacked core layers, the volume of the first connecting structure 171 may not be increased. As a result, by reducing an opening area of the solder resist of the first wiring structure 100 and the solder resist of the interposer 200, the pitch between the first connecting structures 171 or between the first and second connecting structures 171 and 172 may be further reduced.

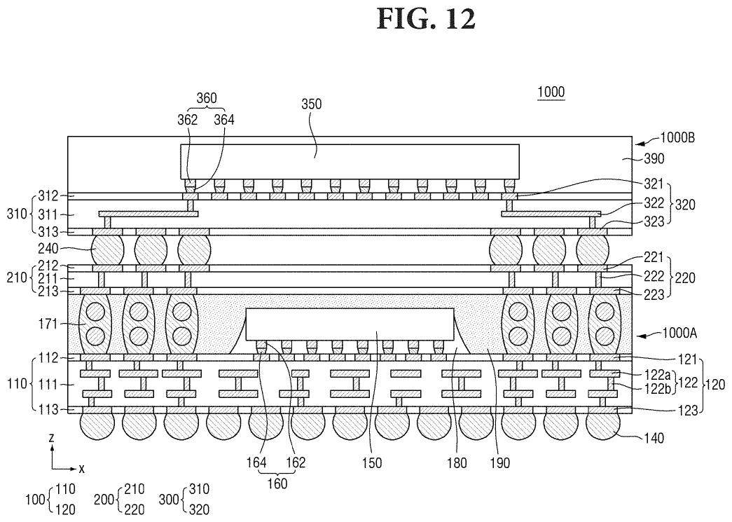

FIG. 12 is a diagram which shows a semiconductor package according to some example embodiments taken along I-I′ of FIG. 4. For convenience of explanation, points different from those described using FIGS. 1 to 6 will be mainly described.

Referring to FIG. 12, a semiconductor package 1000 according to some example embodiments may further include a second semiconductor package 1000B including a second semiconductor chip 350 mounted on a third wiring structure 300 on the first semiconductor package 1000A.

The third wiring structure 300 may be placed on the upper surface of the interposer 200. The third wiring structure 300 may be a wiring structure for packaging. For example, the third wiring structure 300 may be a printed circuit wiring structure (PCB), a ceramic wiring structure, or the like. Alternatively, the third wiring structure 300 may be a wiring structure for a wafer level package (WLP) fabricated at a wafer level. The third wiring structure 300 may include a lower surface and an upper surface that are opposite to each other.

The third wiring structure 300 may include a third insulating layer 310 and a third wiring layer 320. The third insulating layer 310 may include a third substrate 311, a third lower passivation film 313, and a third upper passivation film 312. The third wiring layer 320 may include a third lower pad 323, a third wiring pad 322, and a third upper pad 321.

The third substrate 311 may be, for example, a printed circuit board (PCB) or a ceramic substrate. However, the example embodiments of the inventive concepts are not limited thereto.

When the third substrate 311 is a printed circuit board, the third substrate 311 may be made up of at least one material selected from phenol resin, epoxy resin, and polyimide. The third substrate 311 may include, for example, at least one material selected from FR-4, tetrafunctional epoxy, polyphenylene ether, epoxy/polyphenylene oxide, BT (bismaleimide triazine), thermount, cyanate ester, polyimide, and liquid crystal polymer, but example embodiments are not limited thereto.

The surface of the third substrate 311 may be covered with a solder resist. That is, the third lower passivation film 313 and the third upper passivation film 312 formed on the surface of the third substrate 311 may be solder resists. However, the example embodiments of the inventive concepts are not limited thereto.

The third wiring layer 320 may be placed inside the third insulating layer 310. The third wiring layer 320 may be made up of a third wiring pad 322 for electrically connecting the third lower pad 323 and the third upper pad 321. The third wiring pad 322 may include a plurality of wirings and a plurality of vias for connecting each wiring.

Although the third substrate 311 is shown as being a single layer, this is only for convenience of explanation. For example, the third substrate 311 is made up of multiple layers and may form the third wiring pad 322 having multiple layers.

The third upper passivation film 312 and the third upper pad 321 may be formed on the upper surface of the third substrate 311. The third upper passivation film 312 may cover the upper surface of the third substrate 311 and expose the third upper pad 321.

The third lower passivation film 313 and the third lower pad 323 may be formed on the lower surface of the third substrate 311. The third lower passivation film 313 may cover the lower surface of the third substrate 311 and expose the third lower pad 323.

In some example embodiments, the third upper pad 321 may be electrically connected to the third lower pad 323. For example, the third upper pad 321 may be electrically connected to the third lower pad 323 by coming into contact with the third wiring pad 322.

The third lower passivation film 313 and the third upper passivation film 312 may include, for example, but is not limited to, a photoimageable dielectric (PID).

A second connecting terminal 240 may be interposed between the interposer 200 and the third wiring structure 300. The second connecting terminal 240 may come into contact with the upper surface of the interposer 200 and the lower surface of the third wiring structure 300. The second connecting terminal 240 may electrically connect the interposer 200 and the third wiring structure 300. For example, the second connecting terminal 240 may come into contact with the second upper pad 221 of the interposer 200 and the third lower pad 323 of the third wiring structure 300.

The second connecting terminal 240 may have, for example, but is not limited thereto, a spherical shape or an elliptical spherical shape. The second connecting terminal 240 may include, for example, but is not limited to, at least one of tin (Sn), indium (In), lead (Pb), zinc (Zn), nickel (Ni), gold (Au), silver (Ag), copper (Cu), antimony (Sb), bismuth (Bi), and combinations thereof.

The second semiconductor chip 350 may be placed on the third wiring structure 300. For example, the second semiconductor chip 350 may be mounted on the upper surface of the third wiring structure 300. The second semiconductor chip 350 may be an integrated circuit (IC) in which hundreds to millions or more of semiconductor elements are integrated in a single chip.

In some example embodiments, the first semiconductor chip 150 may be a logic chip such as an application processor (AP), and the second semiconductor chip 350 may be a memory chip such as a volatile memory (e.g., DRAM) or a non-volatile memory (e.g., ROM or flash memory).

Although only one second semiconductor chip 350 is shown to be formed on the third wiring structure 300, this is only for convenience of explanation. For example, a plurality of second semiconductor chips 350 may be formed side by side on the third wiring structure 300, or a plurality of second semiconductor chips 350 may be stacked on the third wiring structure 300 in order.

In some example embodiments, the second semiconductor chip 350 may be mounted on the third wiring structure 300 by a flip chip bonding method. For example, a third bump 360 may be formed between the upper surface of the third wiring structure 300 and the lower surface of the second semiconductor chip 350. The third bump 360 may electrically connect the third wiring structure 300 and the second semiconductor chip 350.

The third bump 360 may include, for example, a third pillar layer 362 and a third solder layer 364. Since the third pillar layer 362 and the third solder layer 364 may be similar to the first pillar layer 162 and the first solder layer 164 described above, the following detailed description will be omitted.

In some example embodiments, a second mold layer 390 may be formed on the third wiring structure 300. The second mold layer 390 may cover and protect the third wiring structure 300, the second semiconductor chip 350, and the second bump 360. The second mold layer 390 may include, for example, but is not limited to, an insulating polymer material such as EMC.

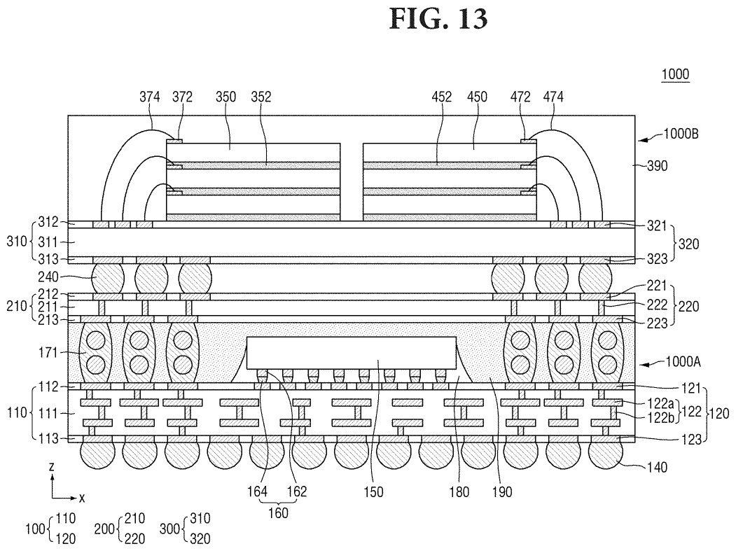

FIG. 13 is a diagram showing a semiconductor package according to some example embodiments taken along I-I′ of FIG. 4. For convenience of explanation, the differences from the semiconductor packages shown in FIGS. 1 to 6 will be mainly described.

Referring to FIG. 13, the semiconductor package according to some example embodiments may include second semiconductor chips 350 and third semiconductor chips 450. The second semiconductor chips 350 and the third semiconductor chips 450 may form a stacked structure. The number of stacked structures and the number of semiconductor chips constituting the stacked structure may vary.

For example, the first semiconductor chip 150 may be a logic chip, and the second semiconductor chips 350 and the third semiconductor chips 450 may be memory chips.

The second semiconductor chips 350 may be mounted on the third wiring structure 300 by the third adhesive layer 352. The third semiconductor chips 450 may be mounted on the third wiring structure 300 by the fourth adhesive layer 452. The third adhesive layer 352 and the fourth adhesive layer 452 may include, for example, but are not limited to, at least one of liquid epoxy, adhesive tape, conductive media and combinations thereof.

The second semiconductor chips 350 may be electrically connected to the third wiring structure 300 by the first bonding wire 374. For example, the first bonding wire 374 may connect the first chip pad 372 to the third upper pad 321 of the third wiring structure 300.

The third semiconductor chips 450 may be electrically connected to the third wiring structure 300 by the second bonding wire 474. For example, the second bonding wire 474 may connect the second chip pad 472 to the third upper pad 321 of the third wiring structure 300.

However, the example embodiments of the inventive concepts are not limited thereto, and the second semiconductor chips 350 and/or the third semiconductor chips 450 may be electrically connected to the third upper pad 321 by, for example, a bonding tape or the like.

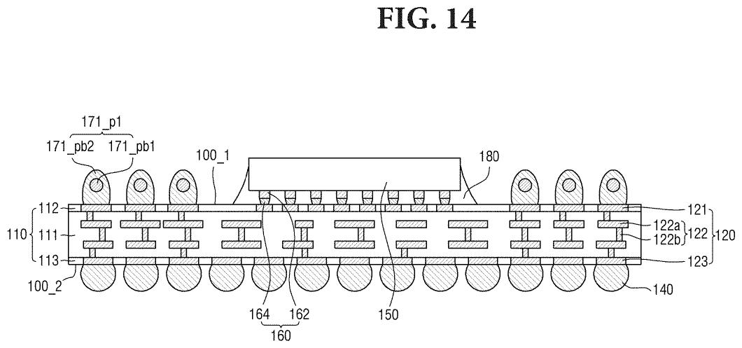

FIGS. 14 to 18 are intermediate stage diagrams for explaining a method of fabricating a semiconductor package according to some example embodiments. For convenience of explanation, the differences from the semiconductor packages shown in FIGS. 1 to 6 will be mainly described.

Referring to FIG. 14, the first wiring structure 100 including the first insulating layer 110 and the first wiring layer 210 and including first and second surfaces 100_1 and 100_2 facing each other is prepared. The first semiconductor chip 150 and a first pre-connecting structure 171_p1 may be formed on the first surface 100_1 of the first wiring structure 100.

In some example embodiments, the first pre-connecting structure 171_p1 may include a first pre-lower metal layer 171_pb1, and a second pre-lower metal layer 171_pb2 surrounding the first pre-lower metal layer 171_pb1.

The first pre-lower metal layer 171_pb1 may include copper (Cu), and the second pre-lower metal layer 171_pb2 may include tin (Sn).

The first semiconductor chip 150 and the underfill material 180 may come into contact with each other. The first semiconductor chip 150 may be connected to the first upper pad 121 of the first wiring structure 100 through the first bump 160.

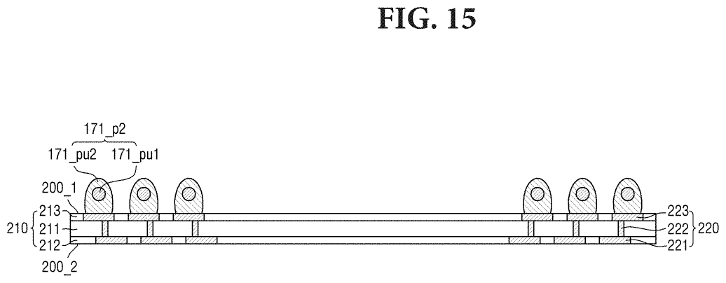

Referring to FIG. 15, the second wiring structure 200 including the second insulating layer 210 and the second wiring layer 220 and including first and second surfaces 200_1 and 200_2 facing each other is prepared. A second pre-connecting structure 171_p2 may be formed on the first surface 200_1 of the second wiring structure 200.

The second pre-connecting structure 171_p2 may include a first pre-upper metal layer 171_pu1, and a second pre-upper metal layer 171_pu2 surrounding the first pre-upper metal layer 171_pu1.

The first pre-upper metal layer 171_pu1 may include copper (Cu), and the second pre-upper metal layer 171_pu2 may include tin (Sn).

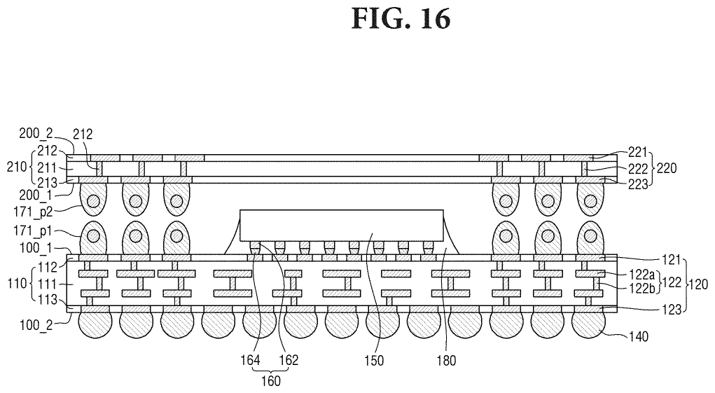

Referring to FIG. 16, the first and second pre-connecting structures 171_p1 and 171_p2 may be aligned so that the first surface 100_1 of the first wiring structure 100 and the first surface 200_1 of the second wiring structure 200 face each other.

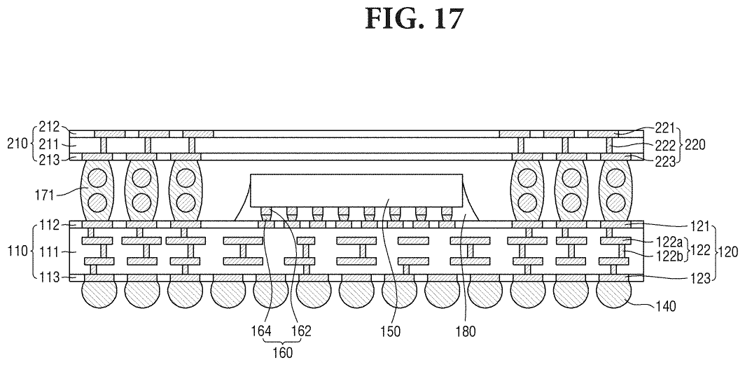

Referring to FIG. 17, the aligned first and second pre-connecting structures 170_p1 and 170_p2 may be joined to form the first connecting structure 171. As a result, the interposer 200 may be stacked on the first wiring structure 100.

Joining of the first and second pre-connecting structures 171_p1 and 171_p2 is performed, for example, by a TC (thermal compression) bonding method in which heat is applied, while pressing the upper surface of the interposer 200 using a bonding mechanism.

Joining of the first and second pre-connecting structures 171_p1 and 171_p2 may include joining of the second pre-lower metal layer 171_pb2 and the second pre-upper metal layer 171_pu2. In some example embodiments, at least a part of the second pre-lower metal layer 171_pb2 and the second pre-upper metal layer 171_pu2 may be melted, and the first pre-lower metal layer 171_pb1 and the first pre-upper metal layer 171_pu1 may not be melted.

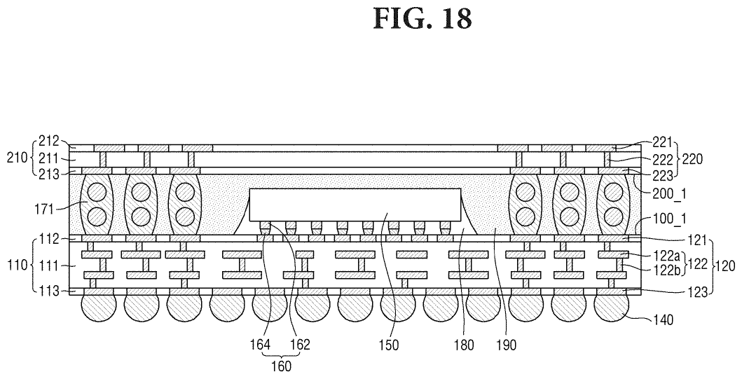

Referring to FIG. 18, a first mold layer 190 that integrally covers the first connecting structure 171 and the first semiconductor chip 150 is formed. The first mold layer 190 may be formed between the first surface 100_1 of the first wiring structure 100 and the first surface 200_1 of the interposer 200. The first mold layer 190 may be formed to be in contact with the upper surface of the first semiconductor chip 150.

The first mold layer 190 may include, but is not limited to, an insulating polymer material such as EMC (epoxy molding compound).

The first connecting structure 171 may be formed outside the first semiconductor chip 150 to support the first wiring structure 100 and the interposer 200.

As a result, the first semiconductor package 1000A shown in FIG. 5 may be formed.

On the other hand, after that, referring to FIG. 12, the second connecting terminal 240 may be formed on the second upper pad 221. The second connecting terminal 240 may electrically connect the interposer 200 and the third wiring structure 300. That is, the semiconductor package 1000 may include a second semiconductor chip 1000B different from the first semiconductor chip 1000A, and the first semiconductor chip 1000A and the second semiconductor chip 1000B may be electrically connected through the second connecting terminal 240.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

In concluding the detailed description, those skilled in the art will appreciate that many variations and modifications may be made to the example embodiments without substantially departing from the inventive concepts. Therefore, the disclosed example embodiments of the invention are used in a generic and descriptive sense only and not for purposes of limitation.

What is claimed is:

1. A semiconductor package comprising:
a wiring structure including a first insulating layer and a first wiring pad, wherein the first wiring pad is in the first insulating layer;
a semiconductor chip on the wiring structure;
an interposer on the semiconductor chip, wherein the interposer includes a second insulating layer and a second wiring pad, and the second wiring pad is in the second insulating layer;
a first connecting structure including a first metal layer and a second metal layer surrounding the first metal layer, wherein the first metal layer includes a lower metal layer adjacent to the wiring structure and an upper metal layer adjacent to the interposer, and the first connecting structure connects the first wiring pad and the second wiring pad; and
a mold layer between the wiring structure and the interposer.

2. The semiconductor package of claim 1, wherein
the first connecting structure is outside the semiconductor chip, and
the first connecting structure is configured to support the wiring structure and the interposer.

3. The semiconductor package of claim 1, wherein the mold layer covers an upper surface of the semiconductor chip.

4. The semiconductor package of claim 1, wherein a thickness of the first connecting structure is the same as a thickness of the mold layer.

5. The semiconductor package of claim 1, wherein the upper metal layer and the lower metal layer are spaced apart from each other.

6. The semiconductor package of claim 1, wherein the upper metal layer and the lower metal layer are in contact with each other.

7. The semiconductor package of claim 1, wherein
the first metal layer includes copper (Cu), and
the second metal layer includes tin (Sn).

8. The semiconductor package of claim 1, wherein the first connecting structure does not include insulating material.

9. The semiconductor package of claim 1, wherein
the wiring structure further includes a third wiring pad spaced apart from the first wiring pad, and the third wiring pad is in the first insulating layer, and
the interposer further includes a fourth wiring pad spaced apart from the second wiring pad, and the fourth wiring pad is in the second insulating layer.

10. The semiconductor package of claim 9, further comprising:
a second connecting structure spaced apart from the first connecting structure, wherein the second connecting structure connects the third wiring pad and the fourth wiring pad,
wherein the second connecting structure includes tin (Sn) and does not include copper (Cu).

11. The semiconductor package of claim 10, wherein a width of the first connecting structure and a width of the second connecting structure are the same.

12. A semiconductor package comprising:
a first semiconductor package; and
a second semiconductor package placed on the first semiconductor package,
wherein the first semiconductor package includes
a wiring structure including a first insulating layer and a first wiring pad, the first wiring pad in the first insulating layer,
a semiconductor chip on a first surface of the wiring structure,
an interposer having a first surface facing the semiconductor chip, the interposer including a second insulating layer and a second wiring pad in the second insulating layer,
a connecting structure between the wiring structure and the interposer, and
a mold layer integrally covering the connecting structure and an upper surface of the semiconductor chip,
wherein the connecting structure includes a plurality of core layers and a metal layer surrounding the plurality of core layers.

13. The semiconductor package of claim 12, wherein
the plurality of core layers include a first core layer and a second core layer stacked on the first core layer,
the first core layer is adjacent to the first surface of the wiring structure,
the second core layer is adjacent to the first surface of the interposer, and
the metal layer connects the first wiring pad and the second wiring pad.

14. The semiconductor package of claim 12, wherein
the connecting structure is outside the semiconductor chip, and
the connecting structure is configured to support the wiring structure and the interposer.

15. The semiconductor package of claim 12, wherein a thickness of the connecting structure is the same as a thickness of the mold layer.

16. The semiconductor package of claim 12, wherein
each of the plurality of core layers includes copper (Cu), and
the metal layer includes tin (Sn).

17. A method of fabricating a semiconductor package, the method comprising:
forming a first wiring structure including a first insulating layer and a first wiring pad, wherein a semiconductor chip and a first pre-connecting structure are on a first surface of the first wiring structure;
forming a second wiring structure including a second insulating layer and a second wiring pad, wherein a second pre-connecting structure is on a first surface of the second wiring structure;
joining the first and second pre-connecting structures with the first surface of the first wiring structure and the first surface of the second wiring structure facing each other to form a connecting structure;
forming a mold layer covering an upper surface of the semiconductor chip, wherein the first pre-connecting structure includes a first pre-lower metal layer and a second pre-lower metal layer surrounding the first pre-lower metal layer, the second pre-connecting structure includes a first pre-upper metal layer and a second pre-upper metal layer surrounding the first pre-upper metal layer; and
joining the second pre-lower metal layer and the second pre-upper metal layer to join the first and second pre-connecting structures.

18. The method of fabricating the semiconductor package of claim 17, wherein
the connecting structure is formed outside the semiconductor chip, and
the connecting structure is configured to support the first wiring structure and the second wiring structure.

19. The method of fabricating the semiconductor package of claim 17, wherein each of the first pre-lower metal layer and the first pre-upper metal layer includes copper (Cu), and
each of the second pre-lower metal layer and the second pre-upper metal layer includes tin (Sn).

20. The method of fabricating the semiconductor package of claim 17, wherein the first and second pre-connecting structures are joined by thermal compression (TC) bonding.
